(19) United States
(12) Patent Application Publication
(10) Pub. No.: US 2024/0266302 A1
(43) Pub. Date: Aug. 8, 2024

(54) CARRIER SUBSTRATE

(71) Applicant: SILICONWARE PRECISION INDUSTRIES CO., LTD., Taichung City (TW)

(72) Inventors: Chung-Yan HUANG, Taichung City (TW); Ning-Hsu CHANG, Taichung City (TW); Wei-Hsin SHIH, Taichung City (TW); Jann-Tzung LIU, Taichung City (TW); Yu-Tung YAO, Taichung City (TW); Hsiu-Fang CHIEN, Taichung City (TW)

(73) Assignee: SILICONWARE PRECISION INDUSTRIES CO., LTD., Taichung City (TW)

(21) Appl. No.: 18/319,591

(22) Filed: May 18, 2023

(30) Foreign Application Priority Data
Feb. 3, 2023 (TW) 112103915

(51) Int. Cl. H01L 23/00; H01L 23/498

(52) U.S. Cl. CPC H01L 23/562; H01L 23/49822; H01L 23/49838

(57) ABSTRACT

A carrier substrate is provided and has a first circuit structure and a second circuit structure on opposing sides of the carrier substrate, where on one routing region, a difference between a routing ratio of a first circuit layer of the first circuit structure and a routing ratio of a second circuit layer of the second circuit structure is within 10%. Therefore, the difference between the routing ratios of the two opposing outermost circuit layers of the carrier substrate in specific target regions can be reduced, so as to avoid a warpage of the carrier substrate due to a great difference in metal distribution areas.

### BACKGROUND

### 1. Technical Field

The present disclosure relates to a chip carrier, and more particularly, to a carrier substrate for carrying semiconductor chips.

### 2. Description of Related Art

In recent years, industrial applications have gradually developed toward 5G high-frequency communication, augmented reality (AR), virtual reality (VR), etc. Therefore, high-level semiconductor packaging technology is required to be applied to semiconductor flip-chip packaging or multi-chip packaging such as artificial intelligence (AI) chips, high-end chips, multiple chips, etc. Under this packaging requirement, the package size is bound to become larger and the number of stacked layers is also higher, so that the circuit design is designed toward high density, fine line pitch, high number of electrical connection points, etc., so as to meet the packaging requirements of aforesaid chips.

In a conventional packaging process, a semiconductor chip is disposed on an upper side of a package substrate, and a packaging colloid is formed to encapsulate the semiconductor chip, then a lower side of the package substrate is disposed on a circuit board via a plurality of solder balls.

However, in the conventional package substrate, routing (e.g., wiring) on an upper side of a circuit layer is densely routed to match high density contacts of the semiconductor chip, while routing on a lower side of the circuit layer is loosely routed to match placement positions of the solder balls. As a result, a metal distribution area on the upper side of the package substrate and a metal distribution area on the lower side of the package substrate are very different (i.e., a difference between routing ratios of the upper side and the lower side of the package substrate is more than 10%). Hence, when the process enters a temperature cycle process such as a process of passing through a reflow oven or a dropping test, the stress distribution between the opposing sides of the package substrate is uneven and warpage is prone to occur, thereby causing the semiconductor chip or the solder balls to crack and resulting in lower product yield.

Therefore, how to overcome the aforementioned drawbacks of the prior art has become an urgent issue for industries to be addressed at present.

### SUMMARY

In view of the various shortcomings of the prior art, the present disclosure provides a carrier substrate, which comprises: a first circuit structure comprising a first dielectric layer and a first circuit layer formed on the first dielectric layer, wherein the first circuit structure is defined with a plurality of first routing regions on an outermost side of the first dielectric layer, such that one of the plurality of first routing regions is defined as a first target region; and a second circuit structure disposed on a side of the first circuit structure, and the second circuit structure comprising a second dielectric layer and a second circuit layer formed on the second dielectric layer, wherein the second circuit structure is defined with a plurality of second routing regions on an outermost side of the second dielectric layer, such that one of the plurality of second routing regions is defined as a second target region with the same shape and area as the first target region, and a position of the first target region and a position of the second target region are overlapped and aligned with each other, so that a difference between a routing ratio of the first circuit layer on the first target region and a routing ratio of the second circuit layer on the second target region is within 10%, wherein the first circuit structure is served as an outer side of the carrier substrate, and the second circuit structure is served as another outer side of the carrier substrate.

In the aforementioned carrier substrate, the present disclosure further comprises a core structure, wherein the second circuit structure is bonded to the first circuit structure via the core structure, such that the first circuit structure and the second circuit structure are disposed on opposing sides of the core structure respectively. For instance, the core structure has a first surface and a second surface opposing the first surface, and the core structure has at least one conductive via in communication with the first surface and the second surface, such that the first circuit structure and the second circuit structure are disposed on the first surface and the second surface of the core structure respectively, and the first circuit structure and the second circuit structure are electrically connected to the conductive via.

In the aforementioned carrier substrate, among the plurality of first routing regions, the first routing region at one corner of a surface of the first dielectric layer is served as the first target region.

In the aforementioned carrier substrate, the routing ratios of the first circuit layer on any two of the plurality of first routing regions are different from each other.

In the aforementioned carrier substrate, at least one of the plurality of first routing regions is used as a chip-placement region for disposing chips, and the routing ratio of the first circuit layer on the chip-placement region is greater than the routing ratio of the first circuit layer on any other one of the plurality of first routing regions.

In the aforementioned carrier substrate, at least one of the plurality of first routing regions is used as a chip-placement region for disposing chips, and the routing ratio of the first circuit layer on the chip-placement region is at least 70%. For instance, the chip-placement region comprises a plurality of the first routing regions.

In the aforementioned carrier substrate, a difference between the routing ratio of the first circuit layer on the outermost side of the first dielectric layer and the routing ratio of the second circuit layer on the outermost side of the second dielectric layer is within 10%.

In the aforementioned carrier substrate, the first circuit structure and the second circuit structure are directly in contact with and bonded to each other.

In the aforementioned carrier substrate, a part of the plurality of first routing regions is defined as the first target region, and another part of the plurality of first routing regions is defined as a third target region, wherein a part of the plurality of second routing regions is defined as the second target region, and another part of the plurality of second routing regions is defined as a fourth target region, wherein a difference between the routing ratio of the first circuit layer on the third target region and the routing ratio of the second circuit layer on the fourth target region is more than 10%.

As can be understood from the above, in the carrier substrate of the present disclosure, the difference between the routing ratio of the first circuit layer on the first target region and the routing ratio of the second circuit layer on the second target region is within 10%, so that the difference between the routing ratios of two opposing outermost circuit layers of the carrier substrate in the specific regions is reduced. Therefore, compared with the prior art, the carrier substrate of the present disclosure can avoid a warping problem due to the difference between metal distribution areas.

### BRIEF DESCRIPTION OF THE DRAWINGS

FIG. 1 is a schematic cross-sectional view of a carrier substrate of the present disclosure.

FIG. 2A is a schematic top view of one side of the carrier substrate of the present disclosure.

FIG. 2B is a schematic top view of the other side of the carrier substrate of the present disclosure.

FIG. 3 is a schematic cross-sectional view showing another aspect of FIG. 1.

FIG. 4 is a schematic cross-sectional view of the carrier substrate according to another embodiment of the present disclosure.

### DETAILED DESCRIPTION

Implementations of the present disclosure are illustrated using the following embodiments. One of ordinary skill in the art can readily appreciate other advantages and technical effects of the present disclosure upon reading the content of this specification.

It should be noted that the structures, ratios, sizes, etc. shown in the drawings appended to this specification are to be construed in conjunction with the disclosure of this specification in order to facilitate understanding of those skilled in the art. They are not meant to limit the implementations of the present disclosure, and therefore have no substantial technical meaning. Any modifications of the structures, changes of the ratio relationships, or adjustments of the sizes, are to be construed as falling within the range covered by the technical content disclosed herein to the extent of not causing changes in the technical effects created and the objectives achieved by the present disclosure. Meanwhile, terms such as “on,” “first,” “second,” “a,” “one,” and the like recited herein are for illustrative purposes, and are not meant to limit the scope in which the present disclosure can be implemented. Any variations or modifications to their relative relationships, without changes in the substantial technical content, should also to be regarded as within the scope in which the present disclosure can be implemented.

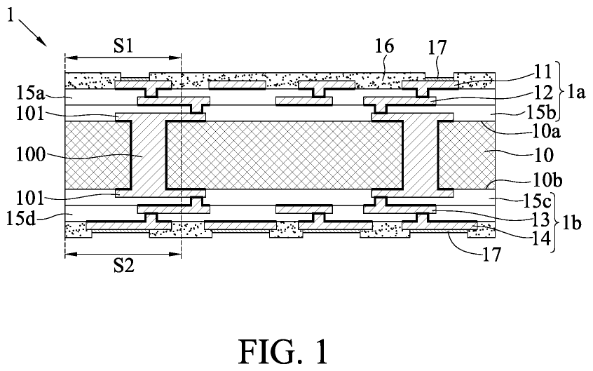

FIG. 1 is a schematic cross-sectional view of a carrier substrate 1 of the present disclosure. As shown in FIG. 1, the carrier substrate 1 comprises a core structure 10, and a first circuit structure 1a and a second circuit structure 1b formed on opposing sides of the core structure 10 respectively.

In an embodiment, opposing sides of the carrier substrate 1 are used as a chip-placement side and a ball-placement side respectively. For instance, the first circuit structure 1a is used as an outer side of the carrier substrate 1 (e.g., the chip-placement side), and the second circuit structure 1b is used as another outer side of the carrier substrate 1 (e.g., the ball-placement side).

The core structure 10 has a first surface 10a and a second surface 10b opposing the first surface 10a, and the core structure 10 has at least one conductive via 100 in communication with the first surface 10a and the second surface 10b.

In an embodiment, the conductive via 100 is formed with electrical connection pads 101 on the first surface 10a and the second surface 10b of the core structure 10.

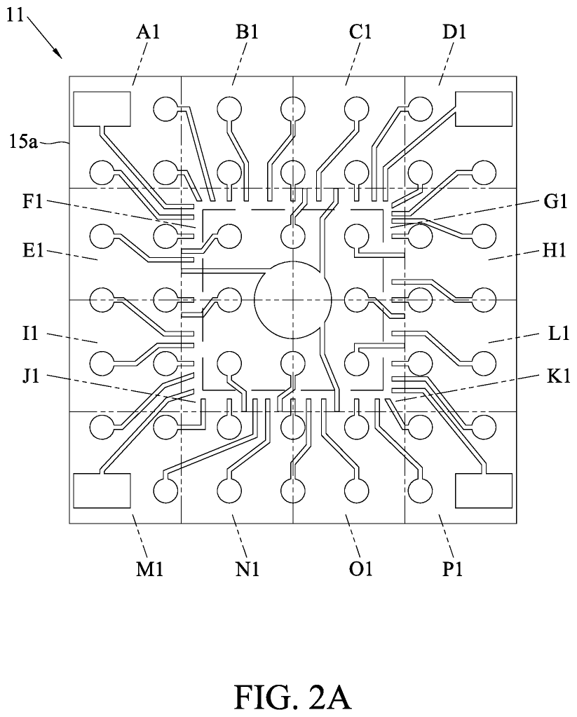

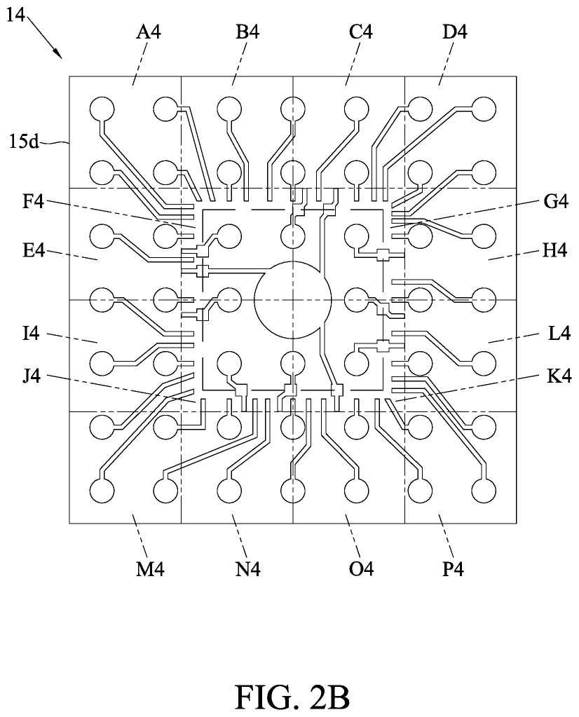

The first circuit structure 1a is disposed on the first surface 10a of the core structure 10, and the first circuit structure 1a comprises a plurality of first dielectric layers 15a, 15b, and first circuit layers 11, 12 disposed on the first dielectric layers 15a, 15b respectively and electrically connected to the electrical connection pads 101 (or the conductive via 100), wherein a plurality of first routing regions A1-P1 are defined on the outermost side of the first dielectric layer 15a of the first circuit structure 1a, as shown in FIG. 2A, and one of the plurality of first routing regions A1-P1 is defined as a first target region S1.

In an embodiment, a surface of the first dielectric layer 15a is a rectangular surface for arranging patterned circuits to serve as the first circuit layer 11, and in an embodiment, sixteen rectangular regions that are equal in area are defined on the surface of the first dielectric layer 15a to serve as the plurality of first routing regions A1-P1, such that the first routing region A1 at one corner of the surface of the first dielectric layer 15a is served as the first target region S1. It can be understood that the quantity and shape of the first routing region are not limited to the above and can be adjusted according to requirements.

Moreover, routing ratios of the first circuit layer 11 on any two of the plurality of first routing regions A1-P1 are different from each other, wherein the routing ratio is a ratio of a specific area on a single dielectric surface region used to route metal circuits. For instance, a rectangular area of the first routing region A1 (or the first target region S1) is 100 square units, and a circuit area thereof occupies 60 square units, therefore the routing ratio of the first circuit layer 11 on the first target region S1 is 60% (i.e., 60/100). Hence, the routing ratio of the first routing region D1 (e.g., 47%) at another corner can be different from the routing ratio of the first routing region E1 (e.g., 35%) on the other side.

Furthermore, the first circuit structure 1a is used as the chip-placement side, thus at least one of the plurality of first routing regions A1-P1 is used as the chip-placement region for disposing chips, so that the routing ratio of the first circuit layer 11 in the chip-placement region is greater than the routing ratio of the first circuit layer 11 on any other one of the plurality of first routing regions A1-P1. For instance, the routing ratio of the first circuit layer 11 on the chip-placement region is at least 70%. It can be understood that the chip-placement region can include a plurality of first routing regions F1, G1, J1, K1, as shown by middle four rectangular regions in FIG. 2A.

In addition, an insulating protection layer 16 such as a solder-resist layer can be formed on the first circuit structure 1a, and the first circuit layer 11 is exposed from the insulating protection layer 16. For instance, a plurality of openings exposing the first circuit layer 11 are formed on the insulating protection layer 16 so as to form a surface treatment layer 17 on the first circuit layer 11 in each of the openings for connecting electronic elements (not shown) such as semiconductor chips in a subsequent process.

The second circuit structure 1b is disposed on the second surface 10b of the core structure 10, such that the second circuit structure 1b is bonded with the first circuit structure 1a via the core structure 10. The second circuit structure 1b comprises a plurality of second dielectric layers 15c, 15d, and second circuit layers 13, 14 disposed on the second dielectric layers 15c, 15d respectively and electrically connected to the electrical connection pads 101 (or the conductive via 100), wherein a plurality of second routing regions A4-P4 are defined on the outermost side of the second dielectric layer 15d of the second circuit structure 1b, as shown in FIG. 2B, such that one of the plurality of second routing regions A4-P4 is defined as a second target region S2 with the same shape and area of the first target region S1, and a position of the first target region S1 and a position of the second target region S2 are overlapped and aligned with each other, so that a difference between the routing ratio of the first circuit layer 11 on the first target region S1 and the routing ratio of the second circuit layer 14 on the second target region S2 is within 10%.

In an embodiment, a surface of the second dielectric layer 15d is a rectangular surface for arranging patterned circuits to serve as the second circuit layer 14, and in an embodiment, sixteen rectangular regions that are equal in area are defined on the surface of the second dielectric layer 15d to serve as the plurality of second routing regions A4-P4, such that the second routing region A4 at one corner of the surface of the second dielectric layer 15d is served as the second target region S2. It can be understood that the quantity and shape of the second routing region are not limited to the above and can be adjusted according to requirements, as long as the shape and area of the first target region S1 and the second target region S2 are the same and the position of the first target region S1 and the position of the second target region S2 are overlapped and aligned with each other.

Moreover, if the routing ratio of the first circuit layer 11 on the first target region S1 is 60%, then the routing ratio of the second circuit layer 14 on the second target region S2 can be 50%-60% or 60%-70%. It can be understood that the difference between the routing ratio on the first target region S1 and the routing ratio on the second target region S2 only needs to be within 10%, but the present disclosure is not limited to as such. In another embodiment of the present disclosure, the routing ratios of the first circuit layer 11 and the second circuit layer 14 corresponding to each routing region are all less than 10%, for instance, the routing ratios of the first routing region A1 and the second routing region A4 are all less than 10%, the routing ratios of the first routing region B1 and the second routing region B4 are all less than 10%, the routing ratios of the first routing region O1 and the second routing region O4 are all less than 10%, and the routing ratios of the first routing region P1 and the second routing region P4 are all less than 10%.

Furthermore, the second circuit structure 1b is used as the ball-placement side, thus the insulating protection layer 16 such as a solder-resist layer can be formed on the second circuit structure 1b, and the second circuit layer 14 is exposed from the insulating protection layer 16 for connecting conductive elements such as solder balls (not shown) in a subsequent process, so that the carrier substrate 1 is connected to an electronic device such as a circuit board (not shown) via the solder balls. For instance, a plurality of openings exposing the second circuit layer 14 are formed on the insulating protection layer 16 so as to form the surface treatment layer 17 on the second circuit layer 14 in each of the openings for connecting conductive elements such as solder balls (not shown) in a subsequent process.

In addition, the first dielectric layers 15a, 15b and the second dielectric layers 15c, 15d are made of polybenzoxazole (PBO), polyimide (P1), prepreg (PP), epoxy resin, benzocyclobutene (BCB), or other suitable materials, and the first circuit layers 11, 12 and the second circuit layers 13, 14 are made of copper or other metals. For instance, the first circuit layers 11, 12 and the second circuit layers 13, 14 comprise metal circuits for transmitting signals or non-functional metal circuits or metal blocks.

It can be understood that the layer number of the circuit layers of each of the first circuit structure 1a and the second circuit structure 1b can be increased according to requirements and is not limited to two layers in the drawings.

Hence, in the carrier substrate 1 of the present disclosure, the difference between the routing ratios of two opposing outermost circuit layers in specific regions is within 10%, for instance, the difference between the routing ratio of the first circuit layer 11 on the first target region S1 and the routing ratio of the second circuit layer 14 on the second target region S2 is within 10%, such that the warpage of the carrier substrate 1 due to the difference of metal distribution areas of the carrier substrate 1 can be avoided.

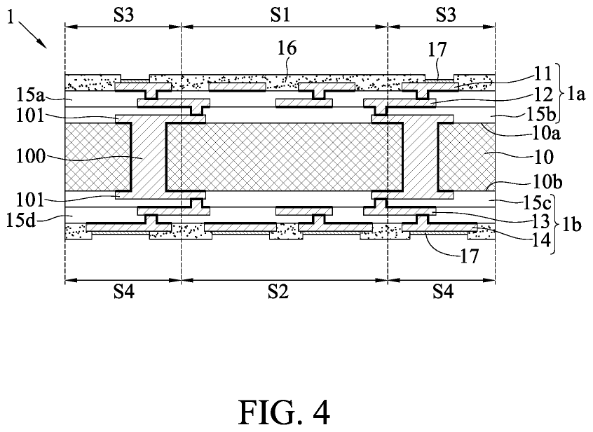

On the other hand, the degree of warpage of the carrier substrate 1 can also be adjusted according to requirements, so that the carrier substrate 1 can be in a warping state to coordinate with subsequent processes, wherein, as shown in FIG. 4, a part of the plurality of first routing regions A1-P1 is defined as the first target region S1, and another part of the plurality of first routing regions A1-P1 is defined as a third target region S3, a part of the plurality of second routing regions A4-P4 is defined as the second target region S2, and another part of the plurality of second routing regions A4-P4 is defined as a fourth target region S4, wherein a difference between the routing ratio of the first circuit layer 11 on the third target region S3 and the routing ratio of the second circuit layer 14 on the fourth target region S4 is more than 10%. For instance, the routing ratio of the first circuit layer 11 on the center of the first target region S1 consisting of first routing regions F1, G1, J1, K1 is less than the routing ratio of the second circuit layer 14 on the center of the second target region S2 consisting of second routing regions F4, G4, J4, K4, and there is a 2% difference between them, and the routing ratio of the first circuit layer 11 on the periphery of the third target region S3 consisting of the first routing regions A1, B1, C1, D1, E1, H1, I1, L1, M1, N1, O1, P1 is less than the routing ratio of the second circuit layer 14 on the periphery of the fourth target region S4 consisting of the second routing regions A4, B4, C4, D4, E4, H4, I4, L4, M4, N4, O4, P4, and there is a 15% difference between them, so that the difference of the routing ratios of the center of the carrier substrate 1 is less than the difference of the routing ratios of the periphery of the carrier substrate 1. In other words, the difference between the routing ratio of the first circuit layer 11 in the central first routing regions F1, G1, J1, K1 and the routing ratio of the second circuit layer 14 in the central second routing regions F4, G4, J4, K4 is less than 10% (e.g., 2%), and the difference between the routing ratio of the first circuit layer 11 in the peripheral first routing regions A1, B1, C1, D1, E1, H1, I1, L1, M1, N1, O1, P1 and the routing ratio of the second circuit layer 14 in the peripheral second routing regions A4, B4, C4, D4, E4, H4, I4, L4, M4, N4, O4, P4 is more than 10% (e.g., 15%), and the routing ratios of the first circuit layer 11 in the central and peripheral first routing regions A1-P1 are all less than the routing ratios of the second circuit layer 14 in the central and peripheral second routing regions A4-P4, whereby the periphery of the carrier substrate 1 is upturned like a smiley face relative to the center of the carrier substrate 1. On the contrary, if the difference of the routing ratios of the center of the carrier substrate 1 is greater than the difference of the routing ratios of the periphery of the carrier substrate 1, then the periphery of the carrier substrate 1 is bent downward like a crying face relative to the center of the carrier substrate 1.

Moreover, in the carrier substrate 1, the difference between the routing ratios of two opposing outermost circuit layers on the entire surface of the dielectric layer is within 10%. For instance, the difference between the routing ratio of the first circuit layer 11 on the outermost side of the first dielectric layer 15a (i.e., all the first routing regions A1-P4) and the routing ratio of the second circuit layer 14 on the outermost side of the second dielectric layer 15d (i.e., all the second routing regions A4-P4) is within 10%, so as to prevent the carrier substrate 1 from warping.

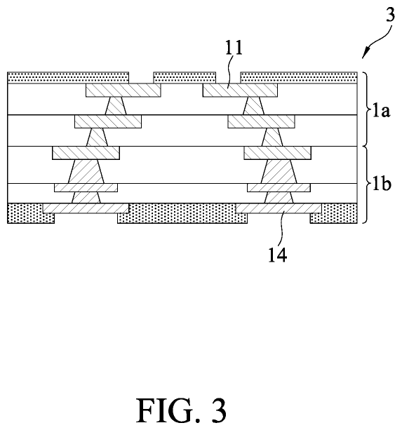

Referring to FIG. 3, in another embodiment, it can be understood that a coreless substrate specification can also be applied to a carrier substrate 3, wherein the first circuit structure 1a and the second circuit structure 1b are directly in contact with and bonded to each other.

To sum up, in the carrier substrate of the present disclosure, the difference between the routing ratios of two opposing outermost circuit layers in specific regions is within 10%, so that the difference between the routing ratios of two opposing outermost circuit layers of the carrier substrate in the specific regions is reduced, thus the warpage of the carrier substrate due to the difference in metal distribution areas can be avoided.

The above embodiments are set forth to illustrate the principles of the present disclosure and the effects thereof, and should not be interpreted as to limit the present disclosure. The above embodiments can be modified by one of ordinary skill in the art without departing from the scope of the present disclosure as defined in the appended claims. Therefore, the scope of protection of the right of the present disclosure should be listed as the following appended claims.

What is claimed is:

1. A carrier substrate, comprising:
a first circuit structure comprising a first dielectric layer and a first circuit layer formed on the first dielectric layer, wherein the first circuit structure is defined with a plurality of first routing regions on an outermost side of the first dielectric layer, such that one of the plurality of first routing regions is defined as a first target region; and
a second circuit structure disposed on a side of the first circuit structure, and the second circuit structure comprising a second dielectric layer and a second circuit layer formed on the second dielectric layer, wherein the second circuit structure is defined with a plurality of second routing regions on an outermost side of the second dielectric layer, such that one of the plurality of second routing regions is defined as a second target region with the same shape and area as the first target region, and a position of the first target region and a position of the second target region are overlapped and aligned with each other, so that a difference between a routing ratio of the first circuit layer on the first target region and a routing ratio of the second circuit layer on the second target region is within 10%,
wherein the first circuit structure is served as an outer side of the carrier substrate, and the second circuit structure is served as another outer side of the carrier substrate.

2. The carrier substrate of claim 1, further comprising a core structure, wherein the second circuit structure is bonded to the first circuit structure via the core structure, such that the first circuit structure and the second circuit structure are disposed on opposing sides of the core structure respectively.

3. The carrier substrate of claim 2, wherein the core structure has a first surface and a second surface opposing the first surface, and the core structure has at least one conductive via in communication with the first surface and the second surface, such that the first circuit structure and the second circuit structure are disposed on the first surface and the second surface of the core structure respectively, and the first circuit structure and the second circuit structure are electrically connected to the conductive via.

4. The carrier substrate of claim 1, wherein among the plurality of first routing regions, the first routing region at one corner of a surface of the first dielectric layer is served as the first target region.

5. The carrier substrate of claim 1, wherein the routing ratios of the first circuit layer on any two of the plurality of first routing regions are different from each other.

6. The carrier substrate of claim 1, wherein at least one of the plurality of first routing regions is used as a chip-placement region for disposing chips, and the routing ratio of the first circuit layer on the chip-placement region is greater than the routing ratio of the first circuit layer on any other one of the plurality of first routing regions.

7. The carrier substrate of claim 1, wherein at least one of the plurality of first routing regions is used as a chip-placement region for disposing chips, and the routing ratio of the first circuit layer on the chip-placement region is at least 70%.

8. The carrier substrate of claim 7, wherein the chip-placement region comprises a plurality of the first routing regions.

9. The carrier substrate of claim 1, wherein a difference between the routing ratio of the first circuit layer on the outermost side of the first dielectric layer and the routing ratio of the second circuit layer on the outermost side of the second dielectric layer is within 10%.

10. The carrier substrate of claim 1, wherein the first circuit structure and the second circuit structure are directly in contact with and bonded to each other.

11. The carrier substrate of claim 1, wherein a part of the plurality of first routing regions is defined as the first target region, and another part of the plurality of first routing regions is defined as a third target region, wherein a part of the plurality of second routing regions is defined as the second target region, and another part of the plurality of second routing regions is defined as a fourth target region, wherein a difference between the routing ratio of the first circuit layer on the third target region and the routing ratio of the second circuit layer on the fourth target region is more than 10%.
